(19) United States
(12) Patent Application Publication
(10) Pub. No.: US 2024/0322088 A1
(43) Pub. Date: Sep. 26, 2024

(54) PHOSPHOR LAYER WITH ADDITIONAL PARTICLES

(71) Applicant: LUMILEDS LLC, San Jose, CA (US)

(72) Inventors: Marcel Rene BOHMER, Eindhoven (NL); Peter Josef SCHMIDT, Aachen (DE)

(73) Assignee: LUMILEDS LLC, San Jose, CA (US)

(21) Appl. No.: 18/680,070

(22) Filed: May 31, 2024

Related U.S. Application Data
(63) Continuation of application No. PCT/US2022/052172, filed on Dec. 7, 2022.
(60) Provisional application No. 63/289,358, filed on Dec. 14, 2021.

(51) Int. Cl. H01L 33/50; H01L 25/075

(52) U.S. Cl. CPC H01L 33/504; H01L 25/0753; H01L 2933/0041

(57) ABSTRACT

A phosphor layer includes phosphor particles and small typically non-luminescent particles, such as nanoparticles. The small particles improve adherence, coherence, and homogeneity of the phosphor layer by accumulating at contact points of the phosphor particles. Their diameter is smaller than those of the phosphor particles. The small particles may be co-deposited with the phosphor particles during electrophoretic deposition, increasing the formulation conductivity during deposition to increase transport speed. The small particles may be catalysts that aid in removal of organic material included in the electrophoretic deposition process.

### CROSS-REFERENCE TO RELATED APPLICATIONS

This application is a continuation of PCT Application PCT/US2022/052172 filed Dec. 7, 2022, which claims benefit of priority to U.S. Provisional Patent Application No. 63/289,358 filed Dec. 14, 2021. Both of the above applications are incorporated herein by reference in its entirety.

### FIELD OF THE INVENTION

The invention relates generally to phosphor layers, including light emitting devices with phosphor layers, and methods of producing such devices.

### BACKGROUND

Wavelength converting materials (generally referred to herein as “phosphors” and “phosphor layers”), that absorb light emitted by the LED and in response emit light of a longer wavelength (“downconverting” the absorbed light), are used in many applications. Often, phosphor layers are combined with light emitting devices, such as semiconductor light emitting diodes.

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

An LED may be combined with a phosphor layer to form a phosphor converted LED (pcLED). Such a pcLED may have an emission spectrum determined by the emission spectrum of the phosphor, or by a combination of the emission spectrum of the LED and that of the phosphor, depending on whether all of light emitted by the LED is absorbed by the phosphor or some of the light emitted by the LED is transmitted through the phosphor to form a portion of the output emission of the pcLED.

The high efficiency of LEDs and pcLEDs compared to conventional filament lightbulbs and fluorescent lights as well as improved manufacturing capability has led to their vastly increased use in a wide range of lighting applications. The compact nature, low power, and controllability of LEDs and pcLEDs has likewise led to their use as light sources in a variety of electronic devices such as cameras and smart phones. LEDs and pcLEDs have been widely used to create different types of displays, matrices and light engines including automotive adaptive headlights, augmented-reality (AR) displays, virtual-reality (VR) displays, mixed-reality (MR) displays, smart glasses and displays for mobile phones, smart watches, monitors and TVs, and flash illumination for cameras in mobile phones. The individual LED or pcLED pixels in these architectures could have an area of a few square millimeters down to a few square micrometers depending on the matrix or display size and its pixel per inch requirements.

For pcLEDs, the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer.

Some pcLEDs, for instance arrays of microLEDs for adaptive automotive headlighting, need a thin phosphor layer for downconversion. A precise control of the layer thickness is required for color control and to avoid color point variations over the device. The application of the phosphor layer can be done by electrophoretic deposition, which is normally followed by a second step such as the infusion of a binder materials, such as silicone or the application of an inorganic layer by atomic layer deposition to bind the phosphor particles to each other and to the LED.

A suitable method to apply a thin phosphor layer is electrophoretic deposition (EPD). The thin phosphor layer may be applied to the surface of a light emitting device. The particles in the suspension are transported to the electrode by an applied electric field. Deposits formed in such a process are often not well-adhering as there is no clearly identified electrochemical reaction causing discharge and fixation of the phosphor particles. The adhesion and therefore the resistance to subsequent processing steps such as cleaning and handling needs to be significantly improved.

### SUMMARY

This specification discloses phosphor layers comprising phosphor particles and with smaller particles that improve the coherence and adherence of the phosphor layer, and a method of producing the same. A phosphor suspension used to form such a phosphor layer may be made in an apolar solvent.

In the disclosed methods, a certain number of small particles, such as nanoparticles, are added to the EPD formulation. These small particles co-deposit with phosphor particles and improve the cohesion of the layer by accumulating in between the phosphor particles both in the wet and the dry state. This leads to a more homogeneous layer with less drying artifacts, better adhesion, less loss of material in cleaning steps such as rinsing and less prone to damage in subsequent handling, for instance before applying binder material or an ALD layer.

The phosphor layer disclosed herein may be advantageously employed in any of the devices and applications listed above in the Background section.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs.

FIG. 3A shows a schematic top view of an electronics board on which an array of pcLEDs may be mounted, and FIG. 3B similarly shows an array of pcLEDs mounted on the electronic board of FIG. 3A.

FIG. 4A shows a schematic cross-sectional view of an array of pcLEDs arranged with respect to waveguides and a projection lens. FIG. 4B shows an arrangement similar to that of FIG. 4A, without the waveguides.

FIG. 5 schematically illustrates an example camera flash system comprising an adaptive illumination system.

FIG. 6 schematically illustrates an example display (e.g., AR/VR/MR) system that includes an adaptive illumination system.

FIG. 7 shows deposition time and weights of a phosphor layer including the small particles.

FIG. 8 shows deposition time and weights of a phosphor layer without the small particles.

FIG. 9 shows a method of depositing a phosphor layer including the small particles.

FIG. 10 shows a light emitting device including a phosphor layer.

FIG. 11 shows a scanning electron microscope image of a phosphor layer.

FIGS. 12A and 12B show a scanning electron microscope image of another phosphor layer.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

FIG. 1 shows an example of an individual pcLED 100 comprising a light emitting semiconductor diode (LED) structure 102 disposed on a substrate 104, and a phosphor layer 106 disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output and color specifications from the pcLED. The phosphor may be deposited by electrophoretic deposition (EPD). The resulting phosphor layer may be a thin phosphor layer conforming to the surface of the LED structure.

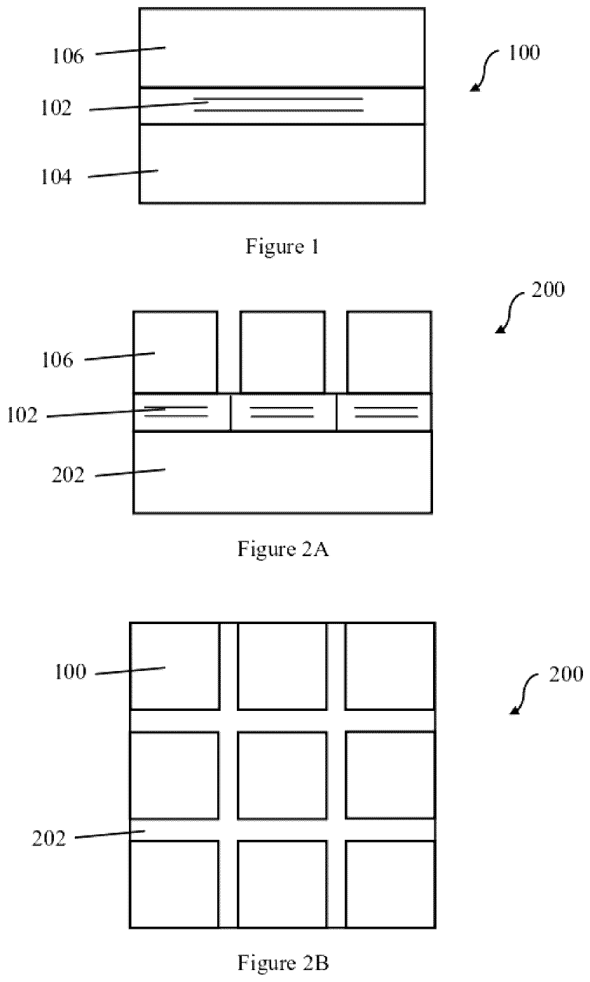

FIGS. 2A-2B show, respectively, cross-sectional and top views of an array 200 of pcLEDs 100 including phosphor pixels 106 disposed on a substrate 202. Such an array may include any suitable number of pcLEDs arranged in any suitable manner. In the illustrated example the array is depicted as formed monolithically on a shared substrate, but alternatively an array of pcLEDs may be formed from separate individual pcLEDs. Substrate 202 may optionally comprise CMOS circuitry for driving the LED and may be formed from any suitable materials.

Although FIGS. 2A-2B, show a three-by-three array of nine pcLEDs, such arrays may include for example tens, hundreds, or thousands of LEDs. Individual LEDs (pixels) may have widths (e.g., side lengths) in the plane of the array, for example, less than or equal to 1 millimeter (mm), less than or equal to 500 microns, less than or equal to 100 microns, or less than or equal to 50 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns. Although the illustrated examples show rectangular pixels arranged in a symmetric matrix, the pixels and the array may have any suitable shape or arrangement.

LEDs having dimensions in the plane of the array (e.g., side lengths) of less than or equal to about 50 microns are typically referred to as microLEDs, and an array of such microLEDs may be referred to as a microLED array.

An array of LEDs, or portions of such an array, may be formed as a segmented monolithic structure in which individual LED pixels are electrically isolated from each other by trenches and/or insulating material, but the electrically isolated segments remain physically connected to each other by portions of the semiconductor structure.

The individual LEDs in an LED array may be individually addressable, may be addressable as part of a group or subset of the pixels in the array, or may not be addressable. Thus, light emitting pixel arrays are useful for any application requiring or benefiting from fine-grained intensity, spatial, and temporal control of light distribution. These applications may include, but are not limited to, precise special patterning of emitted light from pixel blocks or individual pixels. Depending on the application, emitted light may be spectrally distinct, adaptive over time, and/or environmentally responsive. Such light emitting pixel arrays may provide pre-programmed light distribution in various intensity, spatial, or temporal patterns. The emitted light may be based at least in part on received sensor data and may be used for optical wireless communications. Associated electronics and optics may be distinct at a pixel, pixel block, or device level.

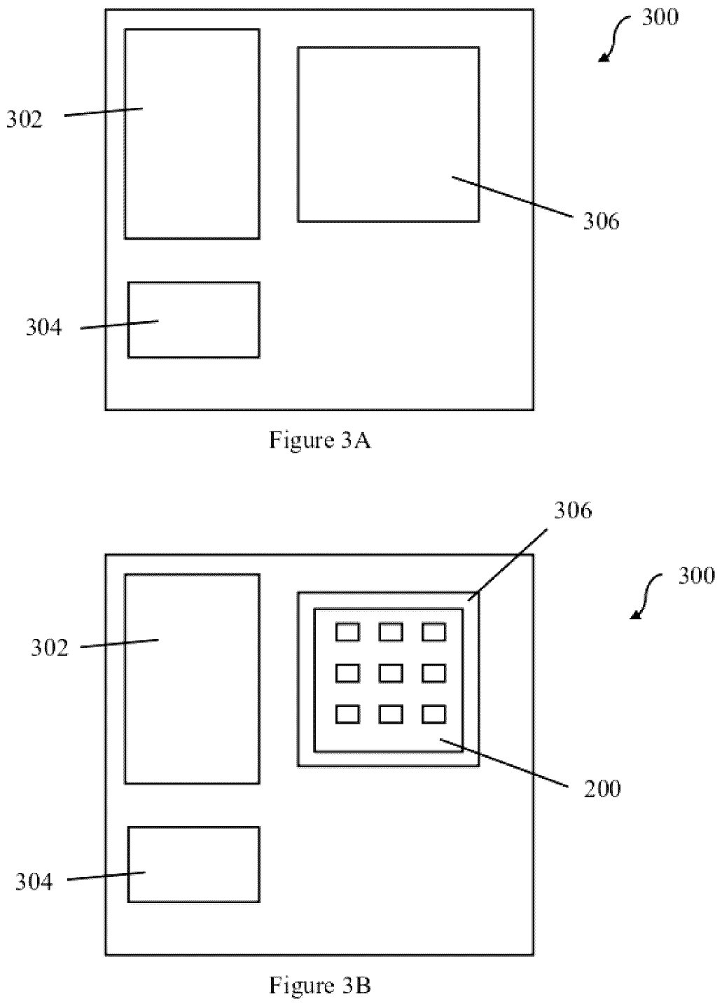

As shown in FIGS. 3A-3B, a pcLED array 200 may be mounted on an electronics board 300 comprising a power and control module 302, a sensor module 304, and an LED attach region 306. Power and control module 302 may receive power and control signals from external sources and signals from sensor module 304, based on which power and control module 302 controls operation of the LEDs. Sensor module 304 may receive signals from any suitable sensors, for example from temperature or light sensors. Alternatively, pcLED array 200 may be mounted on a separate board (not shown) from the power and control module and the sensor module.

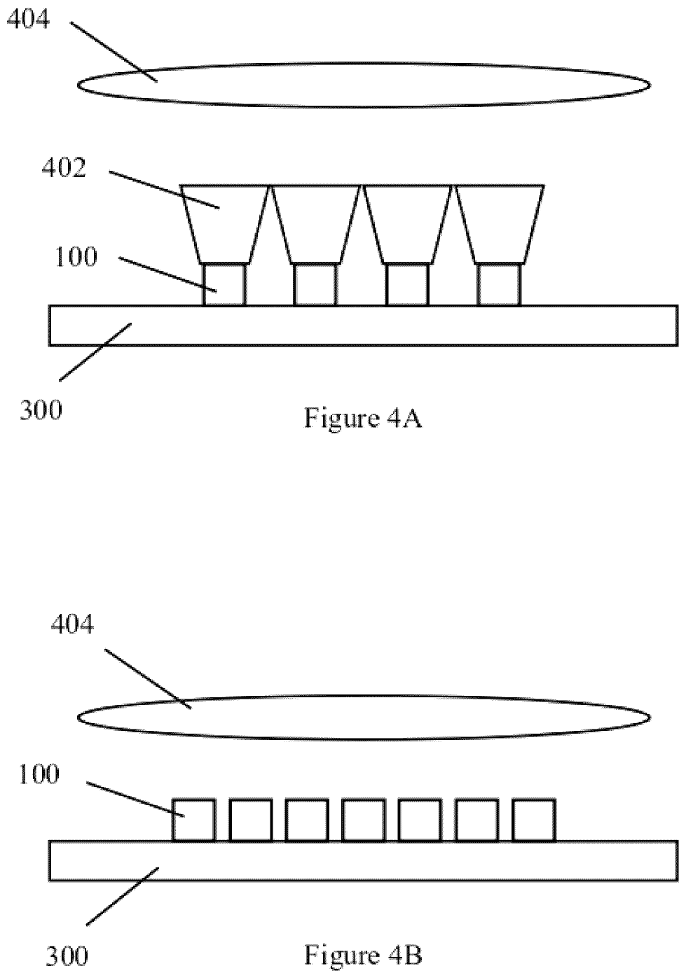

Individual pcLEDs may optionally incorporate or be arranged in combination with a lens or other optical element located adjacent to or disposed on the phosphor layer. Such an optical element, not shown in the figures, may be referred to as a “primary optical element”. In addition, as shown in FIGS. 4A-4B a pcLED array 200 (for example, mounted on an electronics board 300) may be arranged in combination with secondary optical elements such as waveguides, lenses, or both for use in an intended application. In FIG. 4A, light emitted by pcLEDs 100 is collected by waveguides 402 and directed to projection lens 404. Projection lens 404 may be a Fresnel lens, for example. This arrangement may be suitable for use, for example, in automobile headlights. In FIG. 4B, light emitted by pcLEDs 100 is collected directly by projection lens 404 without use of intervening waveguides. This arrangement may be particularly suitable when pcLEDs can be spaced sufficiently close to each other and may also be used in automobile headlights as well as in camera flash applications. A microLED display application may use similar optical arrangements to those depicted in FIGS. 4A-4B, for example. Generally, any suitable arrangement of optical elements may be used in combination with the LED arrays described herein, depending on the desired application.

An array of independently operable LEDs may be used in combination with a lens, lens system, or other optical system (e.g., as described above) to provide illumination that is adaptable for a particular purpose. For example, in operation such an adaptive lighting system may provide illumination that varies by color and/or intensity across an illuminated scene or object and/or is aimed in a desired direction. A controller can be configured to receive data indicating locations and color characteristics of objects or persons in a scene and based on that information control LEDs in an LED array to provide illumination adapted to the scene. Such data can be provided for example by an image sensor, or optical (e.g. laser scanning) or non-optical (e.g. millimeter radar) sensors. Such adaptive illumination is increasingly important for automotive, mobile device camera, VR, and AR applications.

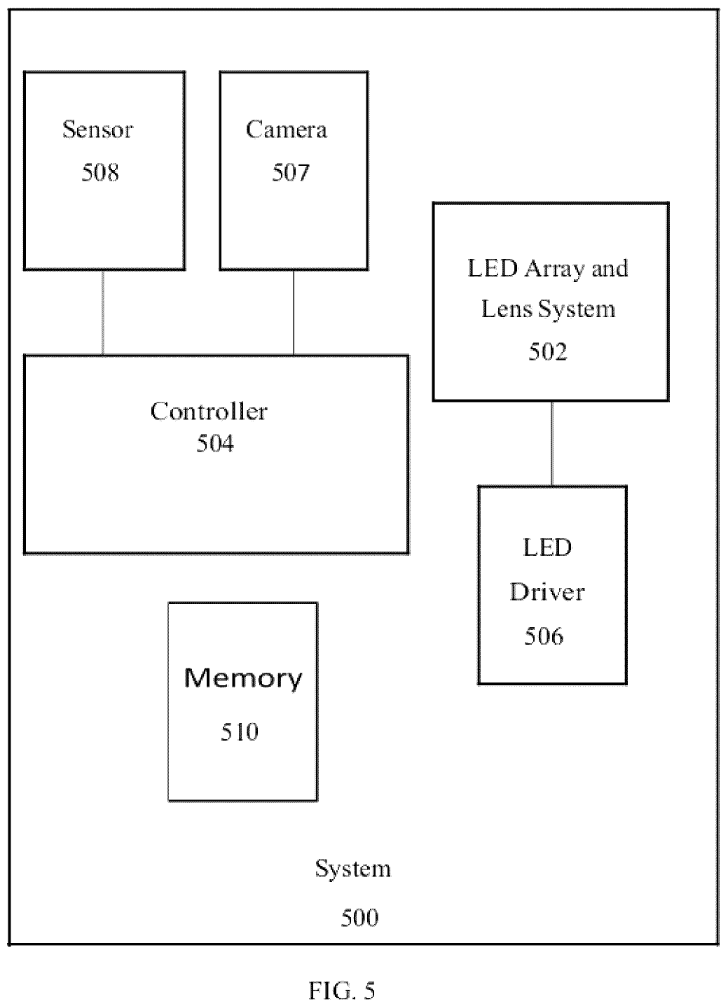

FIG. 5 schematically illustrates an example camera flash system 500 comprising an LED array and lens system 502, which may be similar or identical to the systems described above. Flash system 500 also comprises an LED driver 506 that is controlled by a controller 504, such as a microprocessor. Controller 504 may also be coupled to a camera 507 and to sensors 508, and operate in accordance with instructions and profiles stored in memory 510. Camera 507 and adaptive illumination system 502 may be controlled by controller 504 to match their fields of view.

Sensors 508 may include, for example, positional sensors (e.g., a gyroscope and/or accelerometer) and/or other sensors that may be used to determine the position, speed, and orientation of system 500. The signals from the sensors 508 may be supplied to the controller 504 to be used to determine the appropriate course of action of the controller 504 (e.g., which LEDs are currently illuminating a target and which LEDs will be illuminating the target a predetermined amount of time later).

In operation, illumination from some or all pixels of the LED array in 502 may be adjusted-deactivated, operated at full intensity, or operated at an intermediate intensity. Beam focus or steering of light emitted by the LED array in 502 can be performed electronically by activating one or more subsets of the pixels, to permit dynamic adjustment of the beam shape without moving optics or changing the focus of the lens in the lighting apparatus.

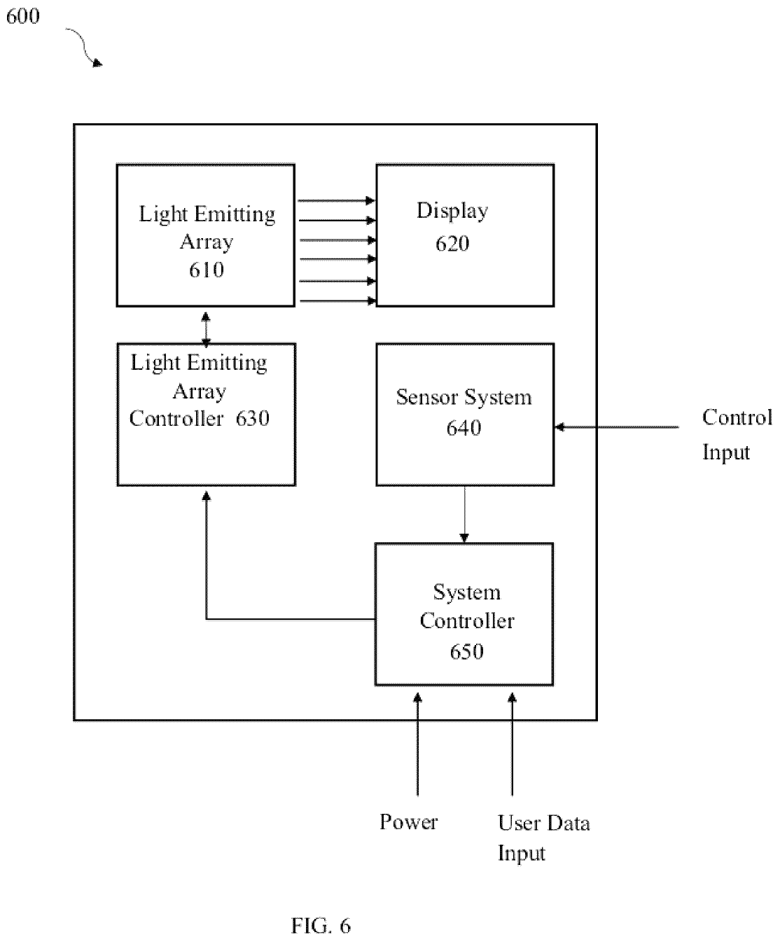

FIG. 6 schematically illustrates an example display (e.g., AR/VR/MR) system 600 that includes an adaptive light emitting array 610, display 620, a light emitting array controller 630, sensor system 640, and system controller 650. Control input is provided to the sensor system 640, while power and user data input is provided to the system controller 650. In some embodiments modules included in system 600 can be compactly arranged in a single structure, or one or more elements can be separately mounted and connected via wireless or wired communication. For example, the light emitting array 610, display 620, and sensor system 640 can be mounted on a headset or glasses, with the light emitting controller and/or system controller 650 separately mounted.

The light emitting array 610 may include one or more adaptive light emitting arrays, as described above, for example, that can be used to project light in graphical or object patterns that can support AR/VR/MR systems. In some embodiments, arrays of microLEDs can be used.

System 600 can incorporate a wide range of optics in adaptive light emitting array 610 and/or display 620, for example to couple light emitted by adaptive light emitting array 610 into display 620.

Sensor system 640 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input can include detected touch or taps, gestural input, or control based on headset or display position.

In response to data from sensor system 640, system controller 650 can send images or instructions to the light emitting array controller 630. Changes or modification to the images or instructions can also be made by user data input, or automated data input as needed. User data input can include but is not limited to that provided by audio instructions, haptic feedback, eye or pupil positioning, or connected keyboard, mouse, or game controller.

As summarized above, in embodiments of the invention a thin phosphor layer is deposited on a surface. The phosphor layer may be deposited by EPD, and the surface upon which it is deposited may be a surface of a light emitting device. In order to deposit the phosphor layer, first a EPD formulation including a suspension of phosphor particles is formed. Such formulations can be prepared with apolar solvents, for instance alkanes. Pure alkanes but also mixtures can be used. The formulation contains the phosphor particles and particles smaller than the phosphor particles, referred to as small particles. The small particles may be non-luminescent.

Additionally, the formulations may contain a charging agent and/or a polymer. The charging agent stabilizes the phosphor particles to form a colloidally stable suspension. The charging agent also provides the particle charge to transport the phosphor particles to the electrode in the applied electric field. Thus, the charging agent may be physically bound to the phosphor particles to serve its purpose. As a result, not only are the bound phosphor particles sensitive to the applied electric field, but they also repel each other, stabilizing the colloidal suspension. Surfactants are typically used as charging agents, such as, for example, Cr-anthralinate (Cr-AN) where the anthranilate is the acid residue of an anthranilic acid which can be substituted at the benzene ring and of which the amino group is acylated with a fatty acid with a chain length of up to 20 C atoms. In an apolar solvent the surfactant form reverse micelles, and the limited charge that is present in these apolar systems is mostly carried in the reverse micelles.

A polymer can also be added to the formulation to interact with the particles and/or the charging agents. The polymer may colloidally stabilize the particles and form a complex with the charging agents, which has an influence on the formation of reverse micelles, and therefore an effect on the conductivity. Polyalkylmethacrylate (PAMA) is one such suitable polymer. The alkyl group in the PAMA can be short (e.g., a methyl group), but it can also be up to 18 (plus) carbon atoms. For example, polyalkylmethacrylates with ester components comprising between 6 and 20 carbon atoms are suitable. Especially suitable are polymethacrylic acid lauryl-stearyl ester containing polymer formulations that are commercially available (various Viscoplex™ grades, Evonik).

Using electrophoretic deposition to deposit particles on surfaces with limited conductivity (i.e., the surface of the light emitting device), a formulation with a low conductivity, in the order of 10 picoSiemens/cm (pS/cm), is suitable. Depending on the phosphor particle loading and the amounts of Cr-AN and PAMA, the conductivity of the formulation with or without small particles can be in the range of 7-100 pS/cm, such as 20-50 pS/cm, such as 30-40 pS/cm. For example, in some formulations without the small particles added, the conductivity of the formulation may be around 10 pS/cm, but with the addition of small particles these particular formulations may then be in the range of 30-40 pS/cm. The presence of the small particles may increase the conductivity of the solution, increasing the electric field and increases transport speed.

The charging agent and polymer may both be organic material. If they are in the formulation, they are co-deposited (i.e., deposited concurrently) with the phosphor particles in the EPD process of forming the phosphor layer. It is desirable to remove any organic material after deposition since they could degrade the layer, for instance causing browning. For example, an ALD coating could lock in the organic material co-deposited on the layer, and since organic material in the layer can no longer oxidize, it can only become carbon and cause browning. Rinsing the layer is not typically an effective way to remove the polymer, though it may be an effective way to remove the charging agent. (Rinsing is, however, an effective way to remove sedimentation on the edge of tape which keeps the contacts of the device clean when EPD is done on the device, as well as removing badly adhering phosphor or other particles when the sample is taken out of the deposition bath). Adding small particles that are co-deposited with the phosphor particles could catalytically remove or help remove the organic material. For example, if the small particles are titania particles, they may photocatalytically aid in removal of the organic material, after the phosphor layer is co-deposited and then subsequently irradiated with UV light. The organic material may then be oxidized and removed from the deposited phosphor layer. The titania particles allow the removal of the organic materials to occur at much lower temperatures than if the organic material were baked out, which would have to occur at much higher temperatures that would damage the phosphor layer. In this way the small particles advantageously allow removal of the organic material at safe temperatures. Alternatively or additionally CeO₂ may be present in the formulation to lower the decomposition temperature of the organic material.

The phosphor particles deposited to form a phosphor layer may be micron-sized. Mixing micron-sized particles with small particles leads to an improvement of the adhesion and the homogencity of the phosphor layer as a whole. The small particles need to be significantly smaller than the phosphor particles, so they can well fit into the space in between the phosphor particles. The small particles tend to accumulate at or around the regions where the phosphor particles are close to or touching each other and/or the surface which they are deposited on, i.e., the contact points of the phosphor particles. Accumulation of these small particles at the weakest points of the phosphor layer mechanically strengthens the layer as a whole, as well as increases adherence to the phosphor layer with the surface the phosphor layer is deposited on. The accumulation of small particles may for example be increased when the drying of the layer happens, and the small particles are dragged to the contact points of the phosphor particles. Normally in drying of the layer the deposited particles experience morphological changes in the layer with the drying fronts. The small particles accumulating at the contact points pin the phosphor particles down and prevents them from moving with the drying fronts.

The phosphor particles may be micron sized, such as from 1 to 50 microns, such as from 2 to 10 microns, such as from 5 to 8 microns. The phosphor particles may have a size distribution with a D50 of for instance 5 micrometers. For micron-sized phosphor particles, small particles of a diameter at or below 300 nm are suitable to obtain these mechanical strengthening advantages, such as at or below 250 nm, at or below 200 nm, or at or below 13 nm. The phosphor particles may also be sub-micron sized, as long as the small particles are much smaller than the phosphor particles. In general, small particles have a diameter that is a ratio of 1 to 5 to the phosphor particles or less (i.e., small particle diameter should be 20% or less of the phosphor particle diameter), and the phosphor particles may be less than 1 micron in size as long as this ratio is maintained. For example, if the small particles are not monodisperse, they may have a diameter that is a ratio of 1 to 10 to the phosphor particles, and this size ratio ensures that particle packing is not disturbed. The small particles may for example be particles of titanium oxide or cerium oxide. The EPD formulation has for example phosphor particles concentrations of from 2% to 10% volume, such as from 2% to 5% volume. The small particle concentrations are for example around 0.1% to 1% volume. The small particle concentrations may also be, separately or additionally, 0.2% to 0.4% the volume of the phosphor particles.

The presence of these small particles should not disturb the optical properties of the phosphor layer. In a specific embodiment the deposition of the phosphor layer is followed by an ALD layer, which increases the mechanical integrity of the final layer. If the small particles are chosen to be of the same material as the material of the ALD layer (such as one or more of Al₂O₃, HfO₂, Ta₂O₅, alone or in combination with each other), no different properties in terms of absorption and refractive index are introduced. A common choice for ALD on phosphors is the growth of an alumina layer. In such a system, alumina small particles are suitable to co-deposit with the phosphor.

If other materials are chosen for ALD, it may be advantageous to change the choice of small particles to be added. Alternatively or additionally to the ALD layer, the particle layer may infused with a silicone to increase its mechanical integrity; in that case, the small particles as silica particles may be useful to co-deposit as they are close to silicone in refractive index. When the ALD is deposited, it may nucleate not just on the phosphor but on the small particles as well, resulting in a different structure than if ALD had nucleated on the phosphor alone. This may occur even if the ALD layer uses the same material as the small particles, and may be detectable by scanning electron microscopy.

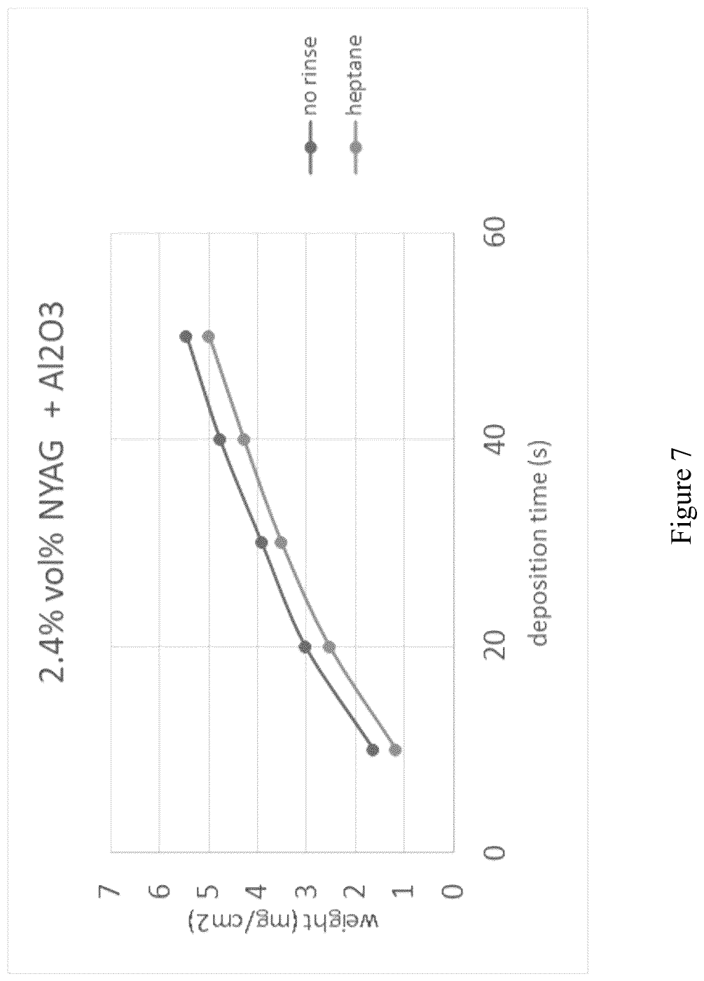

FIG. 7 illustrates an example of electrophoretic deposition of a YAG phosphor having Al₂O₃ particles. The deposition for a YAG based phosphor is given in the presence of Al₂O₃ particles, with an average primary particle size of 13 nm, present at a level of about 1% weight of the phosphor. Both phosphor and alumina are dispersed in an apolar liquid with added Cr-AN and PAMA. When a test sample is removed from the deposition bath and dried the weights as given by the blue dots in FIG. 7 are obtained. When a test sample was first immersed in heptane and then dried, the weights as given in orange are obtained. The weight loss is about 0.5 mg/cm² for all time points/deposited weights in the graph. Apart for rinsing of material, taking a sample out of a deposition batch also give an additional wet film on the sample. After drying this additional film was, in the current experimental set-up about 0.3 mg/cm².

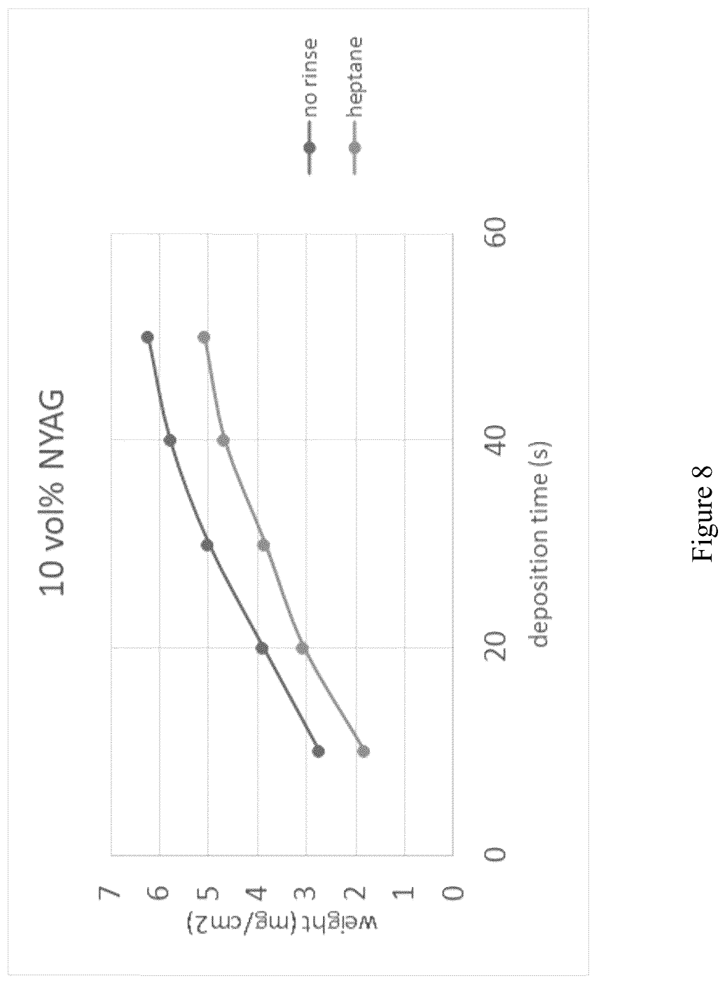

For comparison, the deposition for an YAG based phosphor in the absence of added Al₂O₃ particles is shown in FIG. 8. To obtain similar deposited amounts at the same voltage and deposition time, the phosphor concentration had to be increased from 2.4% to 10 vol %. When a test sample is removed from the deposition bath and dried the weights as given by the blue dots in FIG. 8 are obtained. When a test sample was first immersed in heptane and then dried, the weights as given in orange are obtained. The weight loss is about 1 mg/cm² for all time points/deposited weights in the graph. This demonstrates that the adherence and coherence of the layer are better in the presence of Al₂O₃ while the deposition speed increases 4-fold in the current composition. The difference in the “no rinse” and “heptane” curves is much larger in the deposition without Al₂O₃ particles. That is, less phosphor material is lost in the rinse when the layer contains Al₂O₃ than when the layer does not contain Al₂O₃, meaning the process with Al₂O₃ deposits and keeps phosphor material in the layer more efficiently. Therefore either the EPD time can be shortened, less phosphor can be used or the application voltage can be reduced.

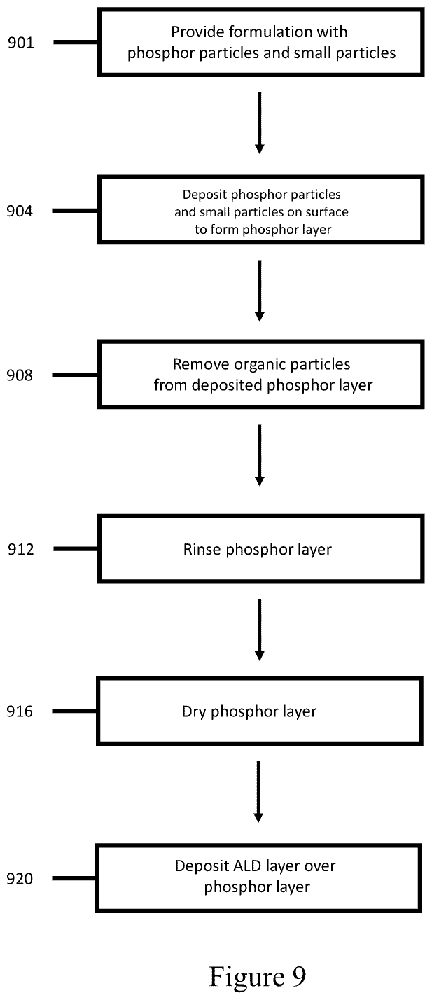

FIG. 9 is a flow chart illustrating an embodiment of the present invention. A phosphor layer is formed on a surface by depositing phosphor particles and other particles on the surface. The surface may be a surface of a light emitting device, such as a a GaN-based LED. Some of the steps illustrated here may be optional depending on the specific formulation used for EPD and other technical or economic considerations. In 901, the formulation is provided to undergo the EPD process. As mentioned above, the formulation must have phosphor particles and small particles. Additionally, the formulation may have a polymer and/or a charging agent, which may be organic material. The formulation is in contact with the surface (e.g., the surface is immersed in the formulation) so that the particles in the formulation may be transported to the surface.

In 904, the phosphor particles and small particles are transported by EPD onto the surface, and as they are deposited, they form a phosphor layer comprising the small particles. If the formulation includes the charging agent and/or polymer, those may also be deposited on the phosphor layer concurrently. In 908, if the charging agent and polymer were deposited in the phosphor layer, then the organic material may be removed from the deposited phosphor layer by any suitable method. The removal may be, for example, by irradiation of the phosphor layer by UV light, which could be catalytically aided by the small particles. In 912, the phosphor layer is rinsed to clean it. The rinsing may be done by immersing the phosphor layer in heptane. In 916, the phosphor layer is dried. Drying may take place in an oven or on a hotplate, with a temperature of 70-100 C.

In 920, after the phosphor layer is dried, an ALD layer may be deposited over the phosphor layer. The ALD layer may be deposited at a thickness of between 50-400 nm, such as between 80-300 nm, such as between 80-120 nm, such as at substantially 100 nm, for example. The ALD layer may be a different material from the small particles, or may be a same material as the small particles.

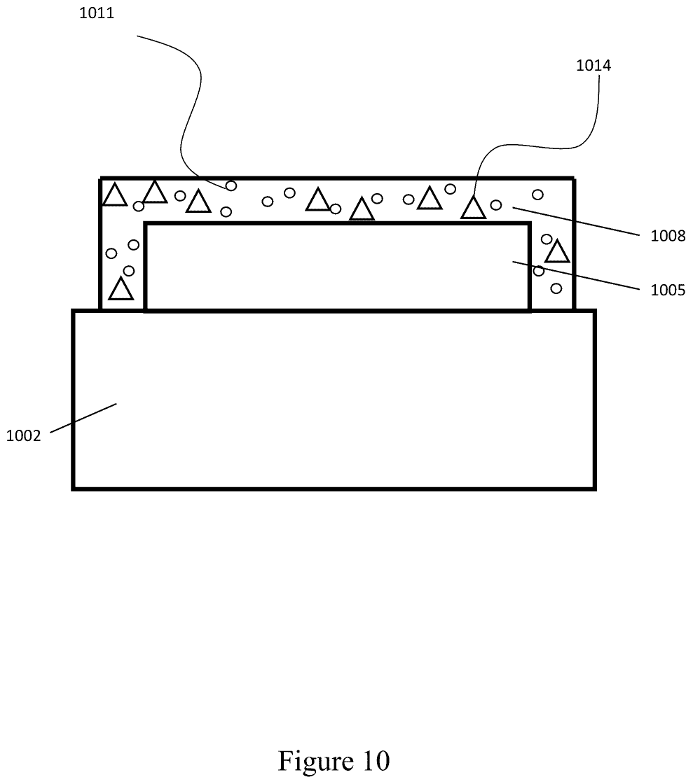

FIG. 10 illustrates an embodiment of the present invention. A phosphor layer 1008 is disposed on the light emitting device 1005. The phosphor layer 1008 conforms to the light emitting surface(s) of the light emitting device 1005. The phosphor layer 1008 comprises small particles 1011 and phosphor particles 1014 (depicted as circles and triangles only for illustrative convenience-they may have any shapes). The phosphor layer 1008 may comprise an ALD layer. The light emitting device 1005 may be disposed on an optional substrate 1002.

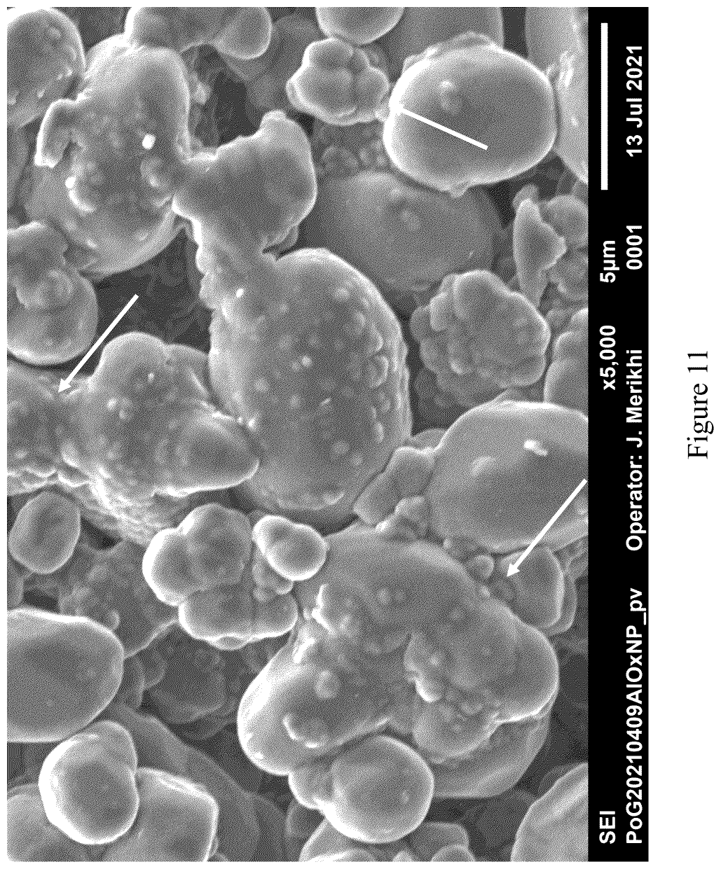

FIG. 11 depicts a scanning electron microscope (SEM) image of a phosphor layer with small particles. Specifically, a phosphor layer applied by EPD with nanoparticles of aluminum-oxide is depicted. Additionally, a 100 nm ALD layer of Al₂O₃ was deposited on the phosphor particles and nanoparticles after EPD. The arrows indicate some examples at which points the nanoparticles have accumulated in between the phosphor particles.

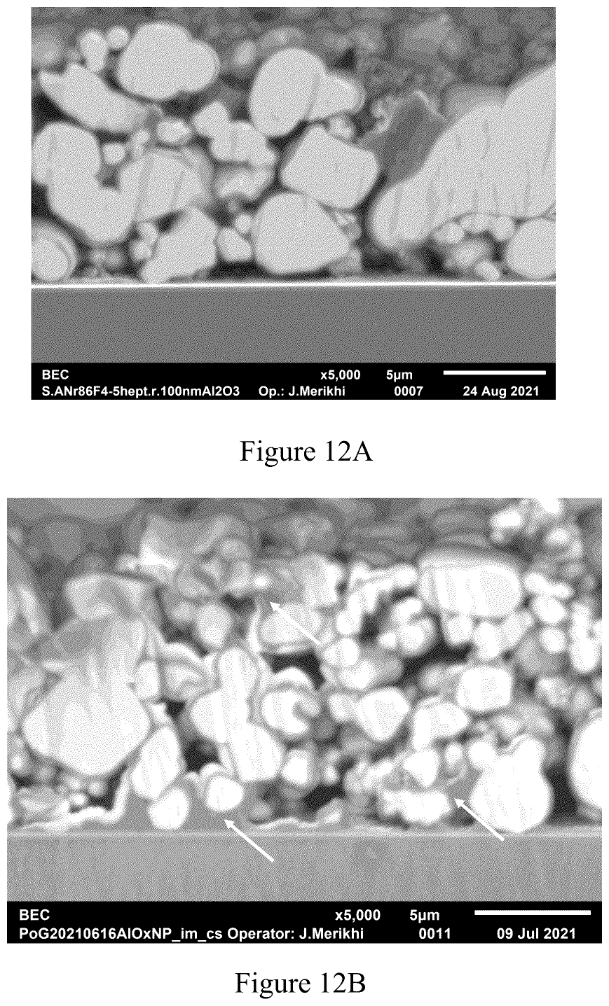

FIG. 12A depicts a cross section of a phosphor layer, applied by electrophoretic deposition, followed by application of a 100 nm ALD layer, which may be the thickness on a flat substrate and/or on single phosphor grains. FIG. 12b depicts another cross section of a phosphor layer, applied by electrophoretic deposition of a 100 nm ALD layer. At locations the ALD layer is thicker than 100 nm as it also nucleates on the alumina nanoparticles, filling up more space in between the phosphor grains, as indicated by the arrows.

This disclosure is illustrative and not limiting. Further modifications will be apparent to one skilled in the art in light of this disclosure and are intended to fall within the scope of the appended claims.

What is claimed is:

1. A method comprising:
providing a surface and a formulation in contact with the surface, the formulation comprising phosphor particles and small particles;
co-depositing the phosphor particles and the small particles on the surface by electrophoretic deposition (EPD) to form a phosphor layer.

2. The method of claim 1, wherein the surface is a surface of a light emitting device.

3. The method of claim 1, wherein the formulation further comprises charging agents physically bound to the phosphor particles, and depositing the phosphor particles and the small particles further comprises depositing the charging agents with the phosphor particles and small particles to form the phosphor layer.

4. The method of claim 1, wherein the charging agent is Cr-anthralinate.

5. The method of claim 1, wherein the formulation further comprises polymers, and depositing the phosphor particles and the small particles further comprises depositing the polymers with the phosphor particles and the small particles to form the phosphor layer.

6. The method of claim 1, wherein the polymer is polyalkylmethacrylate (PAMA).

7. The method of claim 5, further comprising, after depositing the phosphor particles and the small particles, removing the charging agent and the polymer from the phosphor layer.

8. The method of claim 7, wherein removing the charging agent and the polymer comprises irradiating the phosphor layer with UV light.

9. The method of claim 7, wherein the small particles in the phosphor layer catalyze the removing the charging agent and the polymer.

10. The method of claim 1, further comprising, after depositing the phosphor particles, rinsing the phosphor layer.

11. The method of claim 10, further comprising, after rinsing the phosphor layer, depositing by atomic layer deposition (ALD) an ALD layer on the phosphor layer.

12. The method of claim 11, wherein the ALD layer is a different material from the small particles.

13. The method of claim 12, wherein the phosphor particles have diameters at least ten times larger than those of the small particles.

14. The method of claim 13, wherein the formulation has a conductivity in the range of 8 to 100 picoSiemens/cm.

15. A light emitting device, comprising:
a light emitting diode having a light emitting surface;
a phosphor layer on the light emitting surface, the phosphor layer comprising:
phosphor particles each having a first diameter from 2 to 10 microns; and
small particles each having a second diameter of 20% or less than the first diameter of the phosphor particles and comprising a first material of at least one of HfO₂, Ta₂O₅, TiO₂, and CeO₂; and
an atomic layer deposition (ALD) layer comprising the first material.

16. The light emitting device of claim 15, wherein the ALD layer has a thickness of 100 nm or less on the phosphor layer.

17. The light emitting device of claim 16, wherein the small particles each have a diameter at or below 300 nm.

18. The light emitting device of claim 15, wherein the nanoparticle is titanium oxide or cerium oxide.

19. The light emitting device of claim 18, wherein the nanoparticle is cerium oxide.

20. The light emitting device of claim 15, wherein the light emitting surface is not a flat plane and the phosphor layer is conformal on the light emitting surface.
